(19) United States
(12) Patent Application Publication
(10) Pub. No.: US 2024/0181485 A1
(43) Pub. Date: Jun. 6, 2024

(54) VACUUM COATING DEVICE

(71) Applicant: LAPLACE (WUXI) SEMICONDUCTOR TECHNOLOGY CO., LTD., Wuxi (CN)

(72) Inventors: Jia DAI, Wuxi (CN); Henan ZHU, Wuxi (CN); Xuedi DONG, Wuxi (CN); Wu ZHANG, Wuxi (CN); Jiaji LIN, Wuxi (CN)

(73) Assignee: LAPLACE (WUXI) SEMICONDUCTOR TECHNOLOGY CO., LTD., Wuxi (CN)

(21) Appl. No.: 18/438,108

(22) Filed: Feb. 9, 2024

Related U.S. Application Data
(63) Continuation of application No. PCT/CN2022/118600, filed on Sep. 14, 2022.

(30) Foreign Application Priority Data
Jun. 23, 2022 (CN) 202210725491.0

(51) Int. Cl. B05B 15/656; B05B 1/24; B05B 1/32; B05B 15/70; B05B 17/04

(52) U.S. Cl. CPC B05B 15/656; B05B 1/24; B05B 1/32; B05B 15/70; B05B 17/04

(57) ABSTRACT

Disclosed is a vacuum coating device, including a heating apparatus, a loading plate apparatus, a spraying apparatus, a processing chamber and a plurality of valve chambers. The heating apparatus is configured to heat the processing chamber to a temperature that reaches a reaction temperature of the object to be coated and the processing gas, the loading plate apparatus is configured to load the object to be coated, the processing chamber includes a first coating vacuum chamber, a second coating vacuum chamber and a loading plate conversion vacuum chamber, and the loading plate conversion vacuum chamber is configured to convert a coating surface of an object to be coated to achieve a function of coating both sides of the object to be coated on a closed production line, and to improve production quality of the object to be coated.

### CROSS-REFERENCE TO RELATED APPLICATIONS

This application is a continuation of International Application No. PCT/CN2022/118600, filed on Sep. 14, 2022, which claims priority to Chinese Patent Application No. 202210725491.0, filed on Jun. 23, 2022. The disclosures of the aforementioned applications are hereby incorporated by reference in their entireties.

### TECHNICAL FIELD

The present application relates to the field of photovoltaic equipment technologies, and in particular, to a vacuum coating device.

### BACKGROUND

Thin film deposition process is one of the core processes of heterojunction solar cell manufacturing. The thin film deposition process includes several coating processes such as I-type intrinsic amorphous silicon film, P-type amorphous silicon film, N-type amorphous silicon film, and so on. And each coating process needs to be implemented in processing coating chambers.

In the prior art, production lines of the processing coating only coat one side of an object to be coated generally. If it is necessary to coat both sides of the object to be coated, the object to be coated needs to be taken out of the production line, flipped over, and then placed into the production line again. When flipping, the object to be coated comes into contact with air, and water vapor, oxygen, dust, and so on in the air may cause the subsequent performance of the object to be coated to decline.

### SUMMARY

The present application provides a vacuum coating device to achieve the function of coating both sides of an object to be coated on a closed production line, and to improve the production quality of the object to be coated.

The present application provides a vacuum coating device, where the vacuum coating device includes: a plurality of valve chambers; a processing chamber, including a first coating vacuum chamber, a second coating vacuum chamber and a loading plate conversion vacuum chamber, where the loading plate conversion vacuum chamber is connected to the first coating vacuum chamber and the second coating vacuum chamber, the loading plate conversion vacuum chamber is configured to convert a coating surface of an object to be coated, the first coating vacuum chamber and the loading plate conversion vacuum chamber are connected through one of the plurality of valve chambers, the second coating vacuum chamber and the loading plate conversion vacuum chamber are connected through another of the plurality of valve chambers, and the first coating vacuum chamber, the second coating vacuum chamber, the loading plate conversion vacuum chamber and the plurality of valve chambers are configured to form a coating production line for producing the object to be coated; a loading plate apparatus, disposed within the processing chamber, and configured to load the object to be coated; a spraying apparatus, disposed within the processing chamber, and configured to spray a processing gas; and a heating apparatus, configured to heat the processing chamber to a temperature reaching a reaction temperature of the object to be coated and the processing gas.

### BRIEF DESCRIPTION OF THE DRAWINGS

FIG. 1 is a structural schematic diagram of a vacuum coating device according to an embodiment of the present application.

FIG. 2 is a structural schematic diagram of a vacuum chamber, a variable distance structure, a loading plate apparatus, and a transmission structure according to an embodiment of the present application.

FIG. 3 is a structural schematic diagram of a loading plate apparatus and an object to be coated according to an embodiment of the present application.

FIG. 4 is a structural schematic diagram of a vacuum chamber according to an embodiment of the present application.

FIG. 5 is a front view of a vacuum chamber according to an embodiment of the present application.

FIG. 6 is a top view of a vacuum chamber according to an embodiment of the present application.

FIG. 7 is a structural schematic diagram of a transmission structure and a loading plate apparatus according to an embodiment of the present application.

FIG. 8 is a locally enlarged view of region A in FIG. 7 according to an embodiment of the present application.

FIG. 9 is a side view of a transmission structure according to an embodiment of the present application.

FIG. 10 is a locally enlarged view of region B in FIG. 7 according to an embodiment of the present application.

FIG. 11 is a structural schematic diagram of a transmission structure, a loading plate apparatus, and a vacuum chamber according to an embodiment of the present application.

FIG. 12 is a side view of a transmission structure, a loading plate apparatus, and a vacuum chamber according to an embodiment of the present application.

FIG. 13 is a structural schematic diagram of a variable distance structure according to an embodiment of the present application.

FIG. 14 is a structural schematic diagram of a variable distance structure and a loading plate apparatus according to an embodiment of the present application.

FIG. 15 is a structural schematic diagram of a vacuum chamber, a variable distance structure, and a loading plate apparatus according to an embodiment of the present application.

FIG. 16 is a front view of a vacuum chamber according to another embodiment of the present application.

FIG. 17 is a structural schematic diagram of a limit wheel and a gear rack according to an embodiment of the present application.

FIG. 18 is a structural schematic diagram of a limit wheel and a gear rack according to another embodiment of the present application.

FIG. 19 is a structural schematic diagram of a vacuum coating device according to another embodiment of the present application.

### DETAILED DESCRIPTION OF THE EMBODIMENTS

The following examples illustrate the implementation method of the present application, and those skilled in the art may understand other advantages and effects of the present application from the content disclosed in this specification. This application may also be implemented or applied through different specific implementation methods.

It should be noted that the illustrations provided in the following embodiments only illustrate the basic concept of the present application in a schematic manner. Therefore, the illustrations only show the components related to the present application and are not drawn based on the actual number, shape, and size of the components during implementation. In actual implementation, the type, quantity, and proportion of each component may be changed arbitrarily, and the layout of the components may also be more complex.

All directional indications in the embodiments of the present application (such as up, down, left, right, front, back, horizontal, vertical, and so on) are only used to explain the relative position and motion situation between components in a specific posture. If the specific posture changes, the directional indication also changes accordingly.

Due to installation errors and other reasons, the parallel relationship may actually be an approximate parallel relationship, and the vertical relationship may actually be an approximate vertical relationship in the embodiments of the present application.

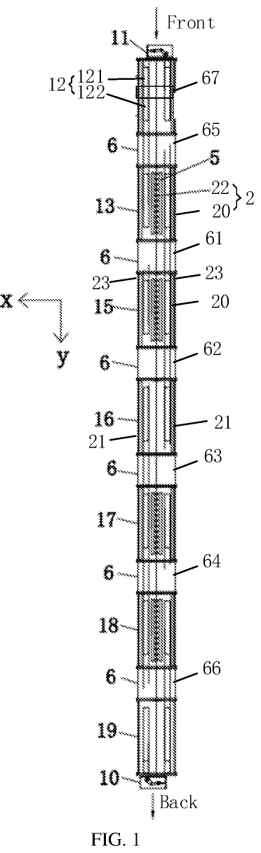

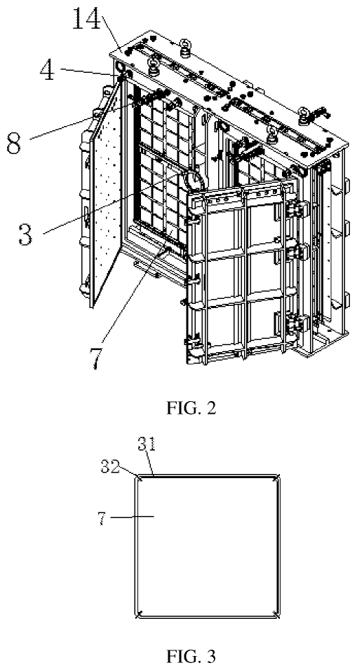

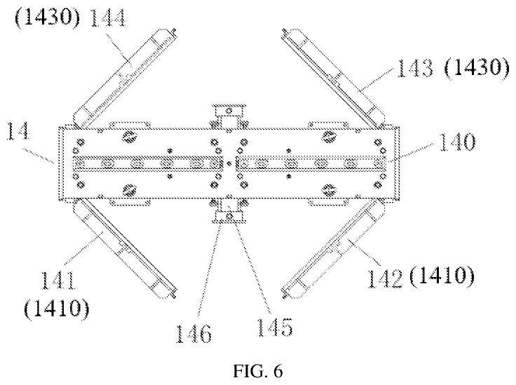

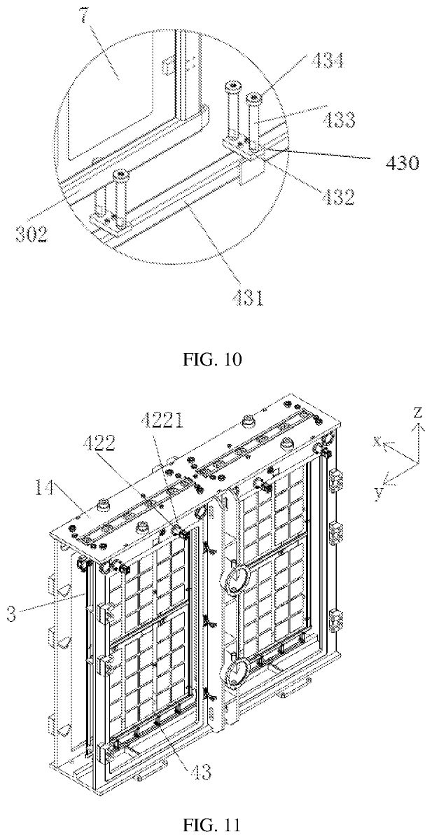

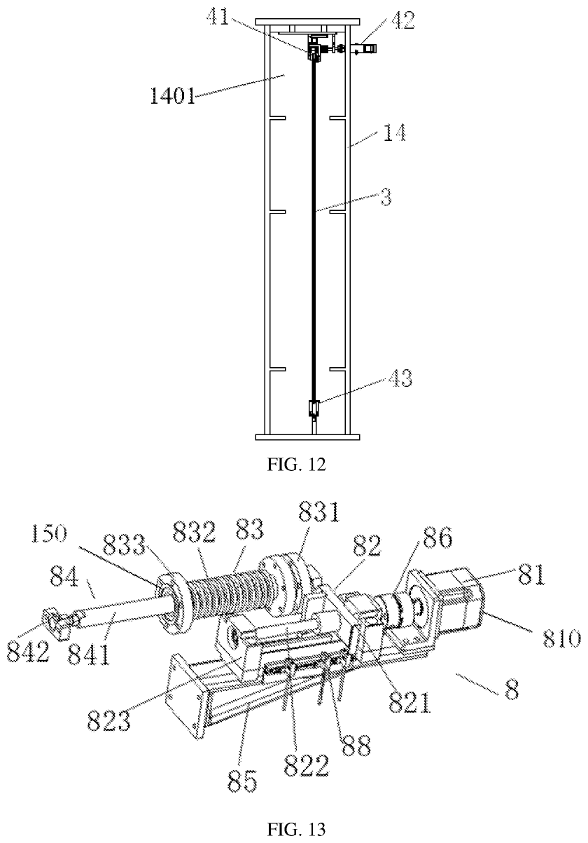

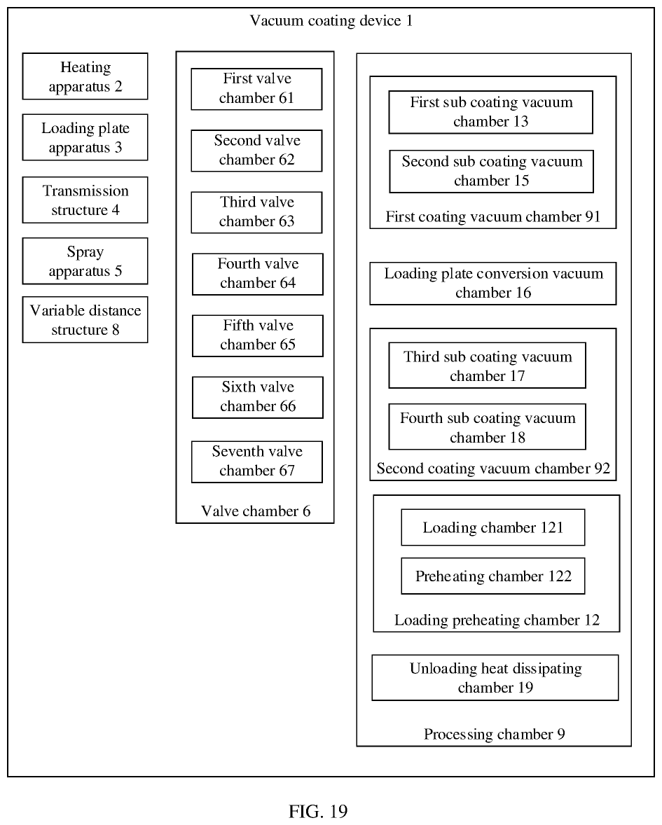

As shown in FIGS. 1 to 19, a vacuum coating device 1 includes a heating apparatus 2, loading plate apparatus 2, a spraying apparatus 5, a plurality of valve chambers 6 and a processing chamber 9. The processing chamber 9 includes a first coating vacuum chamber 91, a second coating vacuum chamber 92, and a loading plate conversion vacuum chamber 16. The loading plate conversion vacuum chamber 16 is connected to the first coating vacuum chamber 91 and the second coating vacuum chamber 92, and the loading plate conversion vacuum chamber 16 is configured to convert the coating surface of an object to be coated 7, the first coating vacuum chamber 91, the second coating vacuum chamber 92 and the loading plate conversion vacuum chamber 16 are connected through a valve chamber 6 of the plurality of valve chambers 6, and the first coating vacuum chamber 91, the second coating vacuum chamber 92, the loading plate conversion vacuum chamber 16 and the plurality of valve chambers 6 form a coating production line 7 for producing the object to be coated. The heating apparatus 2 is configured to heat the processing chamber 9 to a temperature reaching a reaction temperature of the object to be coated 7 and the processing gas. The loading plate apparatus 3 is disposed within the processing chamber 9, and configured to load the object to be coated 7. The spraying apparatus 5 is disposed within the processing chamber 9, and configured to a spray processing gas.

The object to be coated 7 may be a silicon wafer, a glass substrate, and so on.

The plurality of valve chambers 6, the first coating vacuum chamber 91, the second coating vacuum chamber 92, and the loading plate conversion vacuum chamber 16 form a coating production line 7 for producing the object to be coated. And through the coating production line 7 for producing the object to be coated, the double-sided coating of the object to be coated 7 and the conversion of the coating surface of the object to be coated 7 is achieved, thus reducing the area occupied by the coating production line 7 for producing the object to be coated. In this embodiment, the coating production line of the object to be coated 7 may further include a loading preheating chamber 12 and an unloading heat dissipating chamber 19, thus achieving a complete coating process for the object to be coated 7 including preheating, coating, coating surface conversion, and unloading.

In this embodiment, the y-direction in FIG. 1 is the moving direction of the loading plate apparatus 3, and the x-direction in FIG. 1 is perpendicular to the moving direction of the loading plate apparatus 3.

The processing chamber 9 includes the loading preheating chamber 12, the first coating vacuum chamber 91, the second coating vacuum chamber 92, the loading plate conversion vacuum chamber 16, and the unloading heat dissipating chamber 19. The loading preheating chamber 12, the first coating vacuum chamber 91, the second coating vacuum chamber 92, the loading plate conversion vacuum chamber 16, and the unloading heat dissipating chamber 19 may all be vacuum chambers 14. The first coating vacuum chamber 91 includes a first sub coating vacuum chamber 13 and a second sub coating vacuum chamber 15, and the second coating vacuum chamber 92 includes a third sub coating vacuum chamber 17 and a fourth sub coating vacuum chamber 18. The first sub coating vacuum chamber 13 and the second sub coating vacuum chamber 15 are used to coat a first side of the object to be coated 7. The third sub coating vacuum chamber 17 and the fourth sub coating vacuum chamber 18 are used to coat a second side of the object to be coated 7. There is a valve chamber 6 between each vacuum chamber 14, which isolates adjacent vacuum chambers 14 from each other to avoid process pollution. The loading preheating chamber 12 is provided with a first valve 11, and the unloading heat dissipating chamber 19 is provided with a second valve 10. The first valve 11 and the second valve 10 isolate the equipment from the atmospheric environment.

In another embodiment, the heating apparatus 2, the loading plate apparatus 3, and the spray apparatus 5 may also be separately applied to any other vacuum coating device with a vacuum chamber, which may only coat one surface of the object to be coated at a time.

The vacuum chamber 14 is configured to preheat the object to be coated 7, to coat the object to be coated 7, to convert the coating surface of the object to be coated 7, and to provide a room temperature gas to cool the object to be coated 7.

The valve chamber 6 between the first sub coating vacuum chamber 13 and the second sub coating vacuum chamber 15 is a first valve chamber 61, the valve chamber 6 between the second sub coating vacuum chamber 15 and the loading plate conversion vacuum chamber 16 is a second valve chamber 62, the valve chamber 6 between the loading plate conversion vacuum chamber 16 and the third sub coating vacuum chamber 17 is a third valve chamber 63, and the valve chamber 6 between the third sub coating vacuum chamber 17 and the fourth sub coating vacuum chamber 18 is a fourth valve chamber 64.

The first sub coating vacuum chamber 13, the first valve chamber 61, the second sub coating vacuum chamber 15, the second valve chamber 62, the loading plate conversion vacuum chamber 16, the third valve chamber 63, the third sub coating vacuum chamber 17, the fourth valve chamber 64 and the fourth sub coating vacuum chamber 18 are connected sequentially to form a production line of the vacuum coating device 1.

The vacuum coating device 1 further includes a transmission structure 4. The loading plate apparatus 3 for loading the object to be coated 7 is driven by the transmission structure 4 and runs along the production line, thus forming a moving path of the loading plate apparatus 3. Specifically, the moving path of the loading plate apparatus 3 starts from the first sub coating vacuum chamber 13, sequentially passes through the first valve chamber 61, the second sub coating vacuum chamber 15, the second valve chamber 62, the loading plate conversion vacuum chamber 16, the third valve chamber 63, the third sub coating vacuum chamber 17, and the fourth valve chamber 64, and ends at the fourth sub coating vacuum chamber 18.

In some embodiments, the valve chamber 6 between the loading preheating chamber 12 and the first sub coating vacuum chamber 13 is a fifth valve chamber 65. The valve chamber 6 between the fourth sub coating vacuum chamber 18 and the unloading heat dissipating chamber 19 is a sixth valve chamber 66. The moving path of the loading plate apparatus 3 starts from the loading preheating chamber 12, sequentially passes through the fifth valve chamber 65, the first sub coating vacuum chamber 13, the first valve chamber 61, the second sub coating vacuum chamber 15, the second valve chamber 62, the loading plate conversion vacuum chamber 16, the third valve chamber 63, the third sub coating vacuum chamber 17, the fourth valve chamber 64, the fourth sub coating vacuum chamber 18, the sixth valve chamber 66, and ends at the unloading heat dissipating chamber 19.

In this embodiment, the loading preheating chamber 12, the fifth valve chamber 65, the first sub coating vacuum chamber 13, the first valve chamber 61, the second sub coating vacuum chamber 15, the second valve chamber 62, the loading plate conversion vacuum chamber 16, the third valve chamber 63, the third sub coating vacuum chamber 17, the fourth valve chamber 64, the fourth sub coating vacuum chamber 18, the sixth valve chamber 66, and the unloading heat dissipating chamber 19 may be distributed in the form of an assembly line, thereby shortening the moving path of the loading plate apparatus 3 and reducing occupied area of the equipment.

The heating apparatus 2 includes a temperature regulating device 20 and a heat source 22. The loading preheating chamber 12, the first coating vacuum chamber 91, the second coating vacuum chamber 92, and the loading plate conversion vacuum chamber 16 are provided with a pair of temperature regulating devices 20 individually, the temperature regulating devices 20 are symmetrically disposed relative to a centerline of the vacuum coating device 1. In this embodiment, the direction of the centerline of the vacuum coating device 1 is in the y-direction, and the centerline of each vacuum chamber 14 is collinear with the centerline of the vacuum coating device 1. The heat source 22 is disposed at the centerline of the first coating vacuum chamber 91 and the second coating vacuum chamber 92. The first coating vacuum chamber 91 and the second coating vacuum chamber 92 are provided with a pair of spray apparatuses 5 individually, and the spray apparatuses 5 are symmetrically disposed relative to the heat source 22.

The heat source 22 may be tantalum wire, tungsten wire, or rhenium wire, and configured to perform hot filament chemical process at high temperatures. The temperature regulating device 20 may be an armored hot wire used for heating.

The transmission structure 4 runs through the production line. The transmission structures 4 are disposed in pair, and symmetrically disposed relative to the centerline of vacuum coating device 1. One transmission structure 4 controls the movement of at least one of the loading plate apparatuses 3, and at least one of the loading plate apparatuses 3 is distributed along the moving path the transmission structure 4. The moving path of the loading plate apparatus 3 is disposed between the spraying apparatus 5 and the temperature regulating device 20, and the spraying apparatus 5 is used to spray a processing gas. In this embodiment, the processing gas refers to special gases used for semiconductors, such as nitrogen based gases, silicon based gases, and oxygen based gases.

In some embodiments, the loading preheating chamber 12 includes a loading chamber 121 and a preheating chamber 122, the loading chamber 121 and the preheating chamber 122 are connected through the valve chamber 6, and the temperature regulating device 20 is disposed inside the preheating chamber 122. The valve chamber 6 between the loading chamber 121 and the preheating chamber 122 may be a seventh valve chamber 67.

The temperature regulating device 20 inside the preheating chamber and the loading plate conversion vacuum chamber are heaters 21, and the temperature regulating devices 20 inside the first coating vacuum chamber and second coating vacuum chamber are coolers 23.

As shown in FIG. 1, the transmission structure 4 and the temperature regulating device 20 are sequentially distributed, along a direction from a centerline of the vacuum chamber to the outside of the vacuum chamber, inside the loading preheating chamber 12 and the loading plate conversion vacuum chamber 16. The heat source 22, the spray apparatus 5, the transmission structure 4 and the temperature regulating device 20 are sequentially distributed, along the direction from the centerline of the vacuum chamber to the outside of the vacuum chamber, inside the first coating vacuum chamber and the second coating vacuum chamber. And the temperature regulating device 20, the heat source 22 and the spray apparatus 5 of each vacuum chamber operate separately.

As shown in FIG. 3, the loading plate apparatus 3 includes a frame 30, a slot 31, and a pin 32. The object to be coated 7 is disposed in the slot 31 through the pin 32. There is no large area of obstruction on both sides of the object to be coated 7, thus increasing the effective area ratio of the coating and achieving the requirement of double-sided coating. The size and quantity of the object to be coated 7 loaded by the loading plate apparatus 3 may be set according to production requirements of customers.

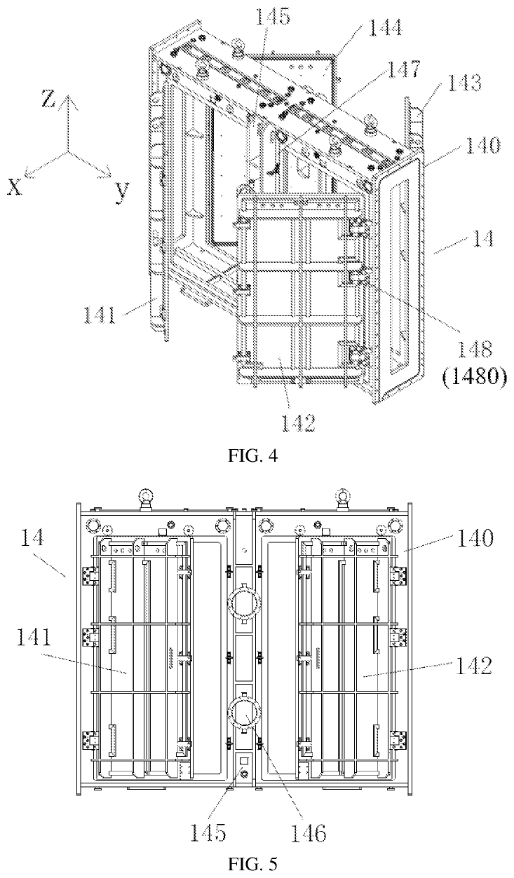

As shown in FIGS. 4 to 6, in this embodiment, the vacuum chamber 14 is a multifunctional vacuum chamber, which may form the loading preheating chamber 12, the first coating vacuum chamber, the second coating vacuum chamber, the loading plate conversion vacuum chamber 16, and the unloading heat dissipating chamber 19. The vacuum chamber 14 may be used for different coating processes, thereby meeting the needs of multifunctional application of the vacuum chamber.

The vacuum chamber 14 includes a chamber frame 140, a front chamber door component 1410 and a back chamber door component 1430. The front chamber door component 1410 and the back chamber door component 1430 are connected through a connection mechanism 1480 and the chamber frame 140, and disposed on both sides of the chamber frame. At least one of the front chamber door component 1410 and the back chamber door component 1430 is configured as a multi-chamber door structure.

In the prior art, the processing coating chamber has the following problems: firstly, some chambers only have one side of the chamber door open, while the other side of the chamber door is closed, making it inconvenient for operators to enter and exit during equipment maintenance and repair, and the operating space is small; secondly, some chamber doors on both sides of the chamber are open, but a mounting flange is reserved on the chamber door, the mounting flange is connected to the dry vacuum pump required by the process, during chamber maintenance, a large number of components need to be removed to open the chamber door, which affects maintenance efficiency; thirdly, the weight of the single-sided chamber door of the chamber is about 2500 kg, and the chamber door relies on hinges to bear weight, thus the load of the hinges is large, which will reduce the service life of the hinges, in addition, the excessive weight of the single-sided chamber door may easily lead to poor structural strength and high safety risks of the chamber door; fourthly, the length of the single-sided chamber door of the chamber is about 2.5 m, thus the area occupied by the opening of the chamber door is large, which will lead to large occupied area of the vacuum chamber.

By including the front chamber door component 1410 and the back chamber door component 1430 in the vacuum chamber 14, and setting at least one of the front chamber door component 1410 and the back chamber door component 1430 as a multi-chamber door structure, the weight and the length of the front chamber door component 1410 and the back chamber door component 1430 may be reduced, the service life of vacuum chamber 14 may be improved, and the occupied area of the vacuum chamber 14 may be saved.

The front chamber door component 1410 and the back chamber door component 1430 are distributed along the x direction. The z direction in FIG. 4 is the height direction of the vacuum chamber, the y direction in FIG. 4 is the moving direction of the loading plate apparatus 3, and the y direction is the length direction of the vacuum chamber.

In this embodiment, the chamber frame 140 is set as a vertical square structure, and a processing chamber is set inside the chamber frame 140. The coating process for the object to be coated 7 is performed in the processing chamber. A partition board 147 is disposed on at least one side of the chamber frame 140, and a beam frame 145 is disposed on a side, away from the chamber frame 140, of the partition board 147. The beam frames 145 on both sides may be symmetrically disposed, with at least one reinforcing rib on it, and at least one dry pump docking flange 146 is distributed along the height direction of the vacuum chamber 14. In an embodiment, the front chamber door component 1410 and the back chamber door component 1430 are hinged with the chamber frame 140. The dry pump docking flange 146 is a flange used for docking with the dry pump.

In this embodiment, the dry pump docking flange 146 is set on the beam frame 145, which no longer interferes with the opening of the chamber door and improves maintenance efficiency.

In some embodiments, the chamber frame 140 is set as a vertical square structure, and a processing chamber is set inside the chamber. The coating process for the object to be coated 7 is performed in the processing chamber. The front chamber door component 1410 includes a front chamber door, and the back chamber door component 1430 includes a back chamber door, so that the chamber frame 140 does not include the partition board 147 and the beam frame 145, the front chamber door component 1410 is a single chamber door structure, and the back chamber door component 1430 is also a single chamber door structure.

In some embodiments, at least one side of the chamber frame 140 is set as a multi chamber door structure, such as the front chamber door component 1410 being set as a single chamber door structure and the back chamber door component 1430 being set s a multi chamber door structure, or the front chamber door component 1410 being set to a multi chamber door structure and the back chamber door component 1430 being set to a single chamber door structure, or both the front chamber door component 1410 and the back chamber door component 1430 being set as multi chamber door structures.

In this embodiment, at least one connection mechanism 1480 is disposed between the front chamber door component 1410 and the chamber frame 140, and at least one connection mechanism 1480 is disposed between the back chamber door component 1430 and the chamber frame 140. In an embodiment, the connection mechanism 1480 may be distributed along the height direction of the vacuum chamber. The connection mechanism 1480 may be set as a hinge 148. The front chamber door component 1410 includes at least one chamber door, and at least one chamber door is distributed along the y-direction. In this embodiment, the number of chamber doors is two, which may include a first chamber door 141 and a second chamber door 142 distributed along the y-direction; the back chamber door component 1430 includes at least one chamber door, and at least one chamber door is distributed along the y-direction, in this embodiment, the number of chamber doors is two, which may include a third chamber door 141 and a fourth chamber door 142 distributed along the y-direction; at least one of the front chamber door component 1410 and the back chamber door component 1430 opens or closes in the y-direction. The first chamber door 141, the second chamber door 142, the third chamber door 143 and the fourth chamber door 144 are respectively connected to the chamber frame 140 through the hinges 148, that is, the chamber door is connected to the chamber frame 140 through the connection mechanism 1480. The number of hinge 148 on either of the first chamber door 141, the second chamber door 142, the third chamber door 143 and the fourth chamber door 144 may be 3, and the 3 hinges 148 are distributed along the height direction of the vacuum chamber to prevent deformation of the hinges 148 and ensure the connection strength between the front chamber door component 1410, the back chamber door component 1430 and the chamber frame 140.

In this embodiment, the partition board 147 is disposed between at least one of the adjacent chamber doors in the front chamber door component 1410 and the back chamber door component 1430.

In this embodiment, the width of the chamber door is not more than 1.5 meters (m), preferably 1.3 meters, and the width direction of the chamber door is in the y-direction. Compared with the single-sided single chamber door structure of the chamber frame 140 in the prior art, this embodiment reduces the weight of a single chamber door, reduces the load on the hinge 148, and improves the service life of the hinge 148 through a multi chamber door structure. At the same time, the size of the chamber door is reduced, thereby reducing the difficulty of production and processing. Under the same conditions, smaller sizes are not easily deformed, which may improve the strength and service life of the chamber door in this embodiment, and have better sealing performance, which may effectively ensure the vacuum degree of the vacuum chamber.

In this embodiment, the first chamber door 141 and second chamber door 142 of the front chamber door component 1410, as well as the third chamber door 143 and the fourth chamber door 144 of the back chamber door component 1430, are opened synchronously, which increases the maintenance space of the equipment, facilitates personnel operation, and improves maintenance efficiency. The area occupied by the opening of the chamber door in this embodiment is half or less comparing to the structure in the prior art, thus reducing the occupied area of the equipment.

In this embodiment, the materials of the chamber frame 140, the front chamber door component 1410, and the back chamber door component 1430 may be aluminum, aluminum alloy, stainless steel, and so on.

In this embodiment, the multi chamber door structure of the vacuum chamber may be applied to the chambers of other devices, not limited to the vacuum coating device.

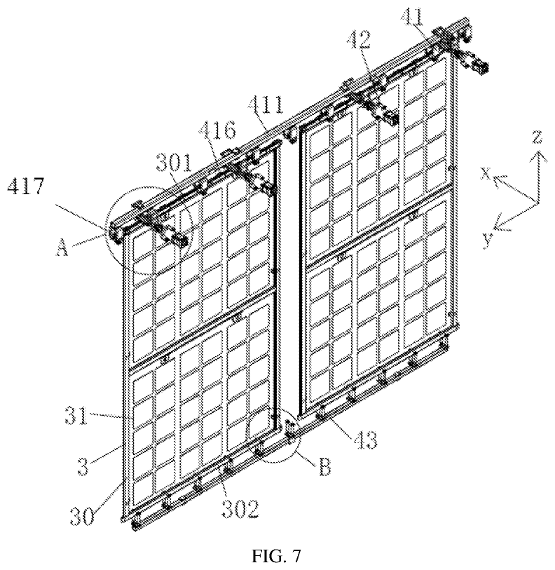

As shown in FIGS. 7 to 12, the transmission structure 4 includes a limit support mechanism 41, a power mechanism 42, and a limit mechanism 43. The limit support mechanism 41 is configured to limit an upper end of the loading plate apparatus 3, the limit support mechanism 41 includes a gear rack 415, and the gear rack 415 is connected to the loading plate apparatus 3. The power mechanism 42 includes a power gear 424, the gear rack 415 meshes with the power gear 424, and a meshing position of the power gear 424 and the gear rack 415 is located at a top of the loading plate apparatus 3. The limit mechanism 43 is configured to limit a lower end of the loading plate apparatus 3.

In the prior art, the transmission efficiency of the transmission structure is low, and the transmission stability is poor. In this embodiment, the power mechanism 42 drives the loading plate apparatus 3 to move through the meshing effect of the power gear 424 and the gear rack 415. The transmission efficiency of the power gear 424 and the gear rack 415 is higher than the transmission efficiency of a roller structure used in the prior art, and the limit accuracy of the transmission between the power gear 424 and the gear rack 415 is high, so that the difference between the operating position of the loading plate apparatus 3 in the chamber and the theoretical value is small, which is conducive to the overall refined management of the equipment. The meshing position between the power gear 424 and the gear rack 415 is located at the top of the loading plate apparatus 3, so that for the large loading plate of the mass production machine, the operational stability of the loading plate apparatus 3 is improved, thus effectively reducing the fragment risk of the object to be coated.

In some embodiments, the meshing transmission between the gear rack 415 and the power gear 424 may be replaced by roller transmission. Specifically, a roller transmission line may be set and used driving mechanisms such as motors to drive the rotation of the rollers. The loading plate apparatus 3 may be set on the rollers, and the rollers drive the loading plate apparatus 3 to move.

The loading plate apparatus 3 includes a frame 30, and the frame 30 includes an upper frame plate 301 and a lower frame plate 302. The upper frame plate 301 and the lower frame plate 302 are distributed in an upward and downward direction, and the upward and downward directions is the z-direction shown in the figure.

The limit support mechanism 41 includes a bracket 411, a support component 417, the gear rack 415 and the power gear 424. The length direction of the bracket 411 is parallel to the moving direction of the loading plate apparatus 3, and the bracket 411 is disposed at the top of the vacuum chamber. The support plate 416 is connected to the loading plate apparatus 3. A number of the power mechanism 42 is plural, and a plurality of power mechanisms 42 are disposed within the vacuum chamber 14 and distributed along the moving direction of the loading plate apparatus 3.

At least one support component 417 is provided, and at least one support component 417 is distributed along the moving direction of the loading plate apparatus 3 and disposed on the bracket 411. The support component 417 includes a wheel mounting bracket 412, a support wheel 413, and a limit wheel 414. The support wheel 413 and the limit wheel 414 are disposed on the wheel mounting bracket 412. The limit wheel 414 is disposed below the gear rack 415 and is configured to form a slot connection with the gear rack 415. A number of the support component 417 is plural, a plurality of support components 417 are distributed along the moving direction of the loading plate apparatus 3 and disposed on the bracket 411. The supporting plate 413 is disposed at the top of the loading plate apparatus 3, and the supporting wheel 413 is disposed on the lower side of the supporting plate 413. During a movement of the loading plate apparatus 3, the support wheel 413 snugly fits with the support plate 416 and supports the support plate 416.

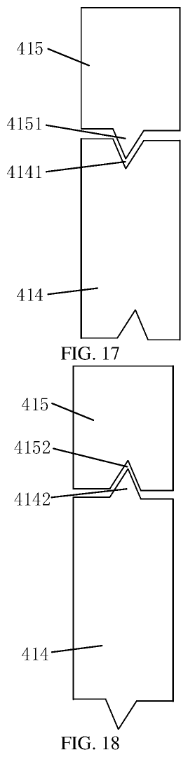

Optionally, the support wheel 413 is disposed below the support plate 416, the support wheel 413 is in contact with the support plate 416, and the limit wheel 414 is disposed below the gear rack 415, so that a slot connection is formed between the limit wheel 414 and the gear rack 415. In an embodiment, the gear rack 415 and the support plate 416 are respectively disposed on the two sides of the upper frame plate 301, the length direction of the gear rack 415 is parallel to the moving direction of the loading plate apparatus 3, and at least one support plate 416 is distributed along the moving direction of the loading plate apparatus 3. The gear rack 415 and the limit wheel 414 are located on the same side, and the support plate 416 and the support wheel 413 are located on the same side. Exemplarily, as shown in FIG. 17, the lower end face of the gear rack 415 is provided with a first block 4151, and the limit wheel 414 is provided with a first slot 4141. The cross-sectional shape of the first block 4151 is the same as the cross-sectional shape of the first slot 4141, for example, the first block 4151 is set as a V-shaped structure, the first slot 4141 is set as a V-shaped slot, and the first block 4151 is buckled into the first slot 4141 to form a slot connection between them. Exemplarily, as shown in FIG. 18, the lower end face of the gear rack 415 is provided with a second slot 4152, and the limit wheel 414 is provided with a second block 4142. The cross-sectional shape of the second block 4142 is the same as the cross-sectional shape of the second slot 4152, for example, the second block 4142 is set as a V-shaped structure, the second slot 4152 is set as a V-shaped slot, and the second block 4142 is buckled into the second slot 4152 to form a slot connection between them. Optionally, the limit wheel 414 adopts the V-shaped wheel in the prior art, and the first block 4151 of the gear rack 415 is set as a V-shaped structure. Through the slot connection between the gear rack 415 and the limit wheel 414, the limit for the loading plate apparatus 3 is achieved, so that the limit of the loading plate apparatus 3 no longer depends on the shape, thus improving the limit accuracy of the loading plate apparatus 3, reducing the machining difficulty of the overall workpiece, and reducing equipment costs.

The support wheel 413 is disposed on a lower side of the support plate 416, and the support wheel 413 snugly fits with the support plate 416 and supports the support plate 416 during a movement of the loading plate apparatus 3. Through the meshing effect between the gear rack 415 and the limit wheel 414 and the support between the support wheel 413 and the support plate 416, suspension support of the loading plate apparatus 3 may be achieved.

The power mechanism 42 includes a motor component 421, a magnetic fluid 422, a coupling 423, a power gear 424, a bearing seat 425 and a power shaft 426. The motor component 421 is disposed outside the vacuum chamber 14. A first end of the magnetic fluid 422 is connected to the motor component 421 and is disposed outside the vacuum chamber 14, and a second end of the magnetic fluid 422 is disposed inside the vacuum chamber 14. The coupling 423 is disposed inside the vacuum chamber 14 and connected to the second end of the magnetic fluid 422. The power shaft 426 is disposed inside the vacuum chamber 14 and connected to the coupling 423, and the power gear 424 is disposed on an outer surface of the power shaft 426. The bearing seat 425 is disposed inside the vacuum chamber 14 and at a top of the vacuum chamber 14, and is configured to carry the power shaft 426 to rotate relative to the bearing seat 425.

Exemplarily, there is a pair of bearing seats 425, which are located on both sides of the limit support mechanism 41 and are set at the top of the vacuum chamber, the vacuum chamber is the working region and moving region of the object to be coated 7; the power shaft 426 runs through the pair of bearing seats 425 and is rotationally connected to the pair of bearing seats 425; the axis of the power shaft 426 is perpendicular to the moving direction of the loading plate apparatus 3; the power gear 424 is disposed on the outer surface of the power shaft 426, the power gear 424 meshes with gear rack 415 to achieve motion transmission; one end of the power shaft 426 is connected to the magnetic fluid 422 through the coupling 423, and the magnetic fluid 422 is connected to the motor component 421 through a fastening mechanism; the axes of the power shaft 426, the coupling 423, the magnetic fluid 422, and the motor component 421 are collinear. As shown in FIG. 11, the coupling 423, the power gear 424, the bearing seat 425, and the power shaft 426 are located inside the vacuum chamber, the motor component 421 and the magnetic fluid 422 are located outside the vacuum chamber, and the mounting surface 4221 of the magnetic fluid 422 is connected to the chamber frame 140 of the vacuum chamber; through the magnetic fluid 422, the inside and the outside of the vacuum chamber are isolated, so that the sealing performance inside the chamber may be ensured; the motor component 421 transfers power to the inside of the vacuum chamber through the magnetic fluid 422.

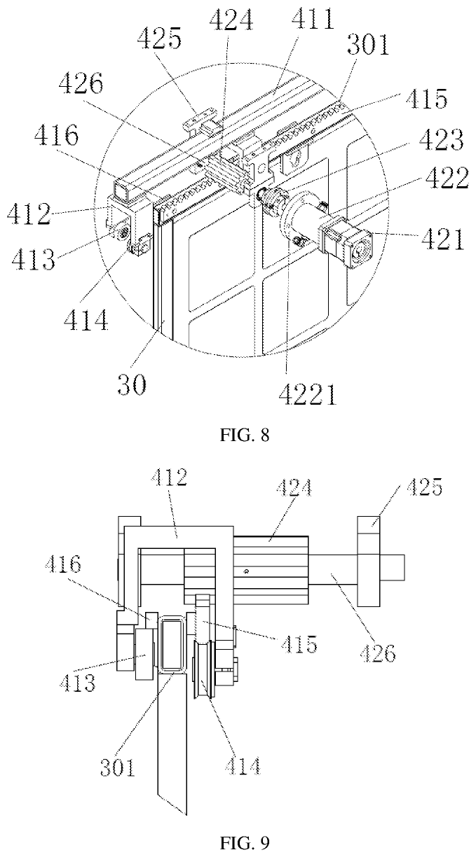

In an embodiment, as shown in FIG. 8, a shape of the magnetic fluid 422 may be a magnetic metal cylinder.

In an embodiment, the magnetic fluid 422 is connected to the motor component 421 through fastening mechanisms such as bolts.

In this embodiment, at least one power mechanism 42 is provided, and at least one power mechanism 42 is distributed, along the moving direction of the loading plate apparatus 3, in the vacuum chamber 14. At least one support component 417 is provided, and at least one support component 417 is distributed, along the moving direction of the loading plate apparatus 3, on the bracket 411, thereby ensuring the limit function and power transmission requirements of the loading plate apparatus 3 during a movement.

Optionally, at least one power mechanism 42 is provided, and at least one power mechanism 42 is disposed, along the moving direction of the loading plate apparatus 3, in the vacuum chamber 14. In this embodiment, at least one power mechanism 42 is provided, and at least one power mechanism 42 is distributed, along the moving direction of the loading plate apparatus 3, in the vacuum chamber 14. At least one support component 417 is provided, and at least one support component 417 is distributed, along the moving direction of the loading plate apparatus 3, on the bracket 411, thereby ensuring the limit function and power transmission requirements of the loading plate apparatus 3 during a movement.

Optionally, the limit mechanism 43 is located at the bottom of the vacuum chamber, the limit support mechanism 41 is connected to the upper end of the loading plate apparatus 3, and the limit mechanism 43 is connected to the lower end of the loading plate apparatus 3. As shown in FIG. 7, the distance between the limit mechanism 43 and the limit support mechanism 41 matches the size, along the height direction of the vacuum chamber, of the loading plate apparatus 3. The limit support mechanism 41 is connected to the upper frame plate 301 of the loading plate apparatus 3 to provide limit support for the upper end of the loading plate apparatus 3, and the limit mechanism 43 is connected to the lower frame plate 302 of the loading plate apparatus 3 to provide limit support for the lower end of the loading plate apparatus 3.

The limit mechanism 43 includes a limit bracket 431 and a limit component 430. The length direction of the limit bracket 431 is parallel to the moving direction of the loading plate apparatus 3, the limit bracket 431 is connected to the bottom inside the vacuum chamber 14, and the limit bracket 431 is parallel to the bracket 411.

Optionally, at least one limit component 430 is provided, and at least one limit component 430 is disposed, along the moving direction of the loading plate apparatus 3, on the limit bracket 431; the limit component 430 includes a limit fixing plate 432 and a pair of limit rods 433, the limit rods 433 are provided with rollers 434, and the rollers 434 are in contact with the end face of the loading plate apparatus 3. Along the moving direction of the loading plate apparatus 3, the size of the lower end of the loading plate apparatus 3 gradually decreases from the middle to both ends. In an embodiment, two limit rods 433 are symmetrically disposed on both sides of the limit fixing plate 432. Two rollers 434 are respectively connected to the limit rods 433 and in contact with both sides of the lower end of the loading plate apparatus 3. The spacing between the rollers 434 is greater than the width of the lower frame plate 302, when the power mechanism 42 drives the loading plate apparatus 3 to move, the lower frame plate 302 of the loading plate apparatus 3 moves between a pair of the limit rods 433 of the limit component 430, the rollers 434 come into contact with the end face of the lower frame plate 302, so that the limitation and restriction of the loading plate apparatus 3 may be achieved, thereby keeping stable during the movement of the loading plate apparatus 3.

To ensure that the lower frame plate 302 of the loading plate apparatus 3 may accurately enter between a pair of limit rods 433 of the limit component 430, the lower frame plate 302 is set with a pointed structure at both ends of its moving direction, that is, the size of the two ends of the lower frame plate 302 gradually decreases, so that it may conveniently and accurately enter between a pair of limit rods 433 between different limit components 430.

In this embodiment, the transmission structure 4 supports the support plate 416 through the support wheel 413, and the limit wheel 414 supports the gear rack 415 to support and limit the loading plate apparatus 3, thereby achieving the suspension and support of the loading plate apparatus 3, and also achieving the limitation and restriction to the loading plate apparatus 3 through the limiting effect of the limit mechanism 43 on the lower frame plate 302. The motor component 421 starts through the rotation of the power gear 424 driven by the magnetic fluid 422 and the coupling 423, and the power gear 424 is meshing connection with the gear rack 415. The rotation of the power gear 424 drives the gear rack 415 to move along the moving space, thereby achieving the movement of the loading plate apparatus 3 between different vacuum chambers.

In this embodiment, the transmission structure 4 may be used for the power transmission of other equipment, and is not limited to the vacuum coating device.

The vacuum coating device 1 further includes a variable distance structure 8. Optionally, a variable distance power component 81 adjusts the distance between the object to be coated 7 loaded by the loading plate apparatus 3 and at least one of the spray apparatus 5 and the heat source 22 through a variable distance transmission component 82, a telescopic component 83, and a docking component 84. As shown in FIGS. 13 to 15, the variable distance structure includes a variable distance power component 81, a variable distance transmission component 82, a telescopic component 83, and a docking component 84. The variable distance power component 81 is connected to the variable distance transmission component 82, the variable distance transmission component 82 is connected to the telescopic component 83, the telescopic component 83 is connected to the docking component 84, and the docking component 84 is connected to the loading plate apparatus 3. The variable distance power component 81 controls movement of the loading plate apparatus 3 through the variable distance transmission component 82, the telescopic component 83, and the docking component 84, for example, controlling the distance between the object to be coated 7 loaded on the loading plate apparatus 3 and at least one of the spray apparatus 5 and the heat source 22.

Thin film deposition process is one of the core processes of heterojunction solar cell manufacturing, and the thin film deposition process includes several coating processes such as I-type intrinsic amorphous silicon film, P-type amorphous silicon film, N-type amorphous silicon film, and so on. In each coating process, the distance between the object to be coated (such as a silicon wafer) and the processing gas spray pipe and the heat source is different. The production line of the object to be coated usually adjusts the distance by manually replacing the installation fixture by operators; this movement not only has low production efficiency, but may also not achieve automated assembly line production, thus resulting in low overall production capacity.

In the process of adjusting the distance between the object to be coated and the processing gas spray pipe, and the heat source, sealing should be maintained. In the prior art, a vacuum sealing cylinder is usually used for sealing, but the vacuum sealing cylinder only has one initial position and one action position, which may only achieve the conversion of two positions and may not achieve distance adjustment.

By setting the variable distance structure 8 and placing it on the vacuum chamber 14, it is possible to adjust several distances (such as the distance between the silicon wafer and the spray apparatus, and the distance between the silicon wafer and the heat source).

In some embodiments, the loading plate apparatus 3 is disposed inside the vacuum chamber 14 through a limit support mechanism 41 and a limit mechanism 43. A docking component 84 includes a docking rod 841 and a docking block 842. A first end of the docking rod 841 is connected to the telescopic component 83, and a second end of the docking rod 841 is connected to the docking block 842, the docking block is disposed inside the vacuum chamber 14, and the docking block 842 is connected to the loading plate apparatus 3 through the limit support mechanism 41.

In some embodiments, the limit support mechanism 41 includes a bracket 411, and the limit mechanism 43 includes a limit bracket 431. The vacuum coating device further includes a sliding apparatus 87, and the sliding apparatus 87 includes a first sliding apparatus 873 and a second sliding apparatus 874.

The first sliding apparatus 873 is disposed between the bracket 411 and the vacuum chamber 14. The first sliding apparatus 873 includes a fixing plate 872 and a sliding block 871, the fixing plate 872 is connected to the vacuum chamber 14, the sliding block 871 is connected to the bracket 411, and the sliding block 871 is slidably connected to the fixing plate 872, so that the sliding block 871 is configured to drive the bracket 411 to move along a direction perpendicular to a length direction of the bracket 411.

The second sliding apparatus 874 is disposed between the limit bracket 43 and the vacuum chamber 14, the second sliding apparatus 874 is respectively connected to the vacuum chamber 14r and the limit bracket 43, and is used to drive the limit bracket 43 to move along a direction perpendicular to a length direction of the limit bracket 43.

The variable distance structure 8 is disposed on the vacuum chamber 14, and further includes a mounting bracket 85. The variable distance power component 81 and variable distance transmission component 82 are disposed on the mounting bracket 85, and the mounting bracket 85 is disposed on the outer side of the vacuum chamber 14. The outer side of the vacuum chamber 14 is located outside the chamber of the vacuum chamber 14.

The variable distance power component 81 includes a motor 810, and the output shaft of the motor 810 is connected to the variable distance transmission component 82 through a first bearing 86 and transmits power to the variable distance transmission component 82.

The variable distance transmission component 82 includes a screw nut 821, a screw rod 822, and a pair of fixing seats 823. A pair of fixing seats 823 is fixed on the mounting bracket 85, and the first end of the screw rod 822 is rotatably connected to a fixed seat 823. The second end of the screw rod 822 rotates through another fixed seat 823 and is connected to the first bearing 86. The variable distance power component 81 transmits power to the screw rod 822 through the first bearing 86, the screw nut 821 is rotatably connected to the screw rod 822, and the screw nut 821 is slidably connected to the mounting bracket 85. When the screw rod 822 rotates, the screw nut 821 moves along the axial direction of the screw rod 822.

The variable distance transmission component 82 further includes an isolation plate 824, and the isolation plate 824 is connected to the mounting bracket 85 and the variable distance power component 81. The isolation plate 824, the mounting bracket 85, and the variable distance power component 81 form an isolation space. The screw nut 821, the screw rod 822, and a pair of fixing seats 823 of the variable distance transmission component 82 are located in the isolation space, and the isolation plate 824 provides a certain protection to the variable distance transmission component 82.

The variable distance structure 8 further includes at least one sensor 88, and the sensor 88 is configured to sense the position of the screw nut 821 to prevent collision between the screw nut 821 and the fixing seat 823.

The telescopic component 83 includes a moving flange 831, a corrugated pipe 832, and a fixing flange 833. The two ends of the corrugated pipe 832 are connected to the moving flange 831 and the fixing flange 833, and the fixing flange 833 is connected to the docking flange 149 on the outer side of the vacuum chamber 14. A sealing ring 150 is disposed between the fixing flange 833 and the docking flange 149 to ensure the sealing between the corrugated pipe 832 and the vacuum chamber 14, so that the corrugated pipe 832 and the vacuum chamber 14 are in the same vacuum environment, the moving flange 831 is connect to the screw nut 821, and the telescopic component 83 is located outside the vacuum chamber 14.

The docking component 84 includes a docking rod 841 and a docking block 842. A first end of the docking rod 841 is inserted into the corrugated tube 832 and connected to the moving flange 831, a second end of the docking rod 841 is connected to the docking block 842, and the docking block 842 is located inside the vacuum chamber 14. The loading plate apparatus 3 loads the object to be coated 7, and the loading plate apparatus 3 is set in the intracavity 1401 of the vacuum chamber 14 through a limit support mechanism 41 and a limit mechanism 43; the limit support mechanism 41 includes a bracket 411, and the limit mechanism 43 includes a limit bracket 431. The length direction of the bracket 411 and the limit bracket 431 is parallel to the moving path of the loading plate apparatus 3 between different vacuum chambers 14; the docking block 842 is respectively connected to the bracket 411 and the limit bracket 431. The sliding apparatus 87 is disposed between the bracket 411 and the limit bracket 431, and the vacuum chamber 14, and the sliding apparatus 87 includes a fixing plate 872 and a sliding block 871, the fixing plate 872 is connected to the vacuum chamber 14, the sliding block 871 is respectively connected to the bracket 411 and the limit bracket 431, and the sliding block 871 is slidably connected to the fixing plate 872.

During the implementation of the variable distance structure 8, the variable distance power component 81 is activated to drive screw rod 822 to rotate; the rotation of screw rod 822 drives the screw nut 821 to move along the axial direction of the screw rod 822. The movement of the screw nut 821 synchronously drives the moving flange 831 to move along the axial direction of the screw rod 822. The moving flange 831 drives the docking block 842 to move, and the movement of the docking block 842 drives the bracket 411 to move. The loading plate apparatus 3 is suspended and supported on the bracket 411, the movement of the bracket 411 synchronously drives the loading plate apparatus 3 to move, thereby achieving the adjustment of the distance between the object to be coated 7 loaded by the loading plate apparatus 3, and at least one of the spray apparatus 5 and the heat source 22; the adjustable range is wide, which may meet the spacing requirements of different objects to be coated and processes. In this embodiment, the fixing flange 833 of the telescopic component 83 is connected to the docking flange 149 on the outer side of the vacuum chamber 14, the sealing ring 150 is disposed between the fixing flange 833 and the docking flange 149 to ensure the sealing between the corrugated pipe 832 and the vacuum chamber 14. The moving flange 831 is connected to the variable distance transmission component 82 to achieve reciprocating movement of the loading plate apparatus 3 along the axial direction, and to achieve the adjustment of the distance between the object to be coated 7 loaded by the loading plate apparatus 3, and at least one of the spray apparatus 5 and the heat source 22.

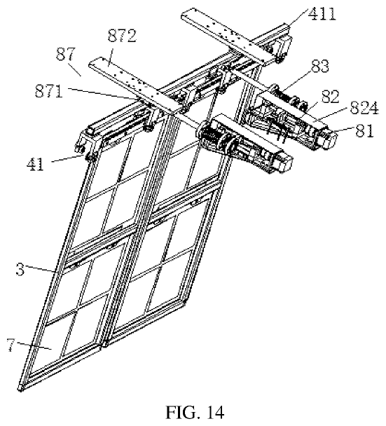

As shown in FIG. 14, a plurality of variable distance structures 8 are provided, and are distributed along the height direction of the vacuum chamber 14 at the upper and lower ends of the vacuum chamber 14; the plurality of variable distance structures 8 are distributed along the moving path of the loading plate apparatus 3, thus ensuring the stable of the loading plate apparatus 3 during the distance adjustment process.

In this embodiment, the variable distance structure 8 may be used for the distance adjustment of other equipment, and is not limited to the vacuum coating device.

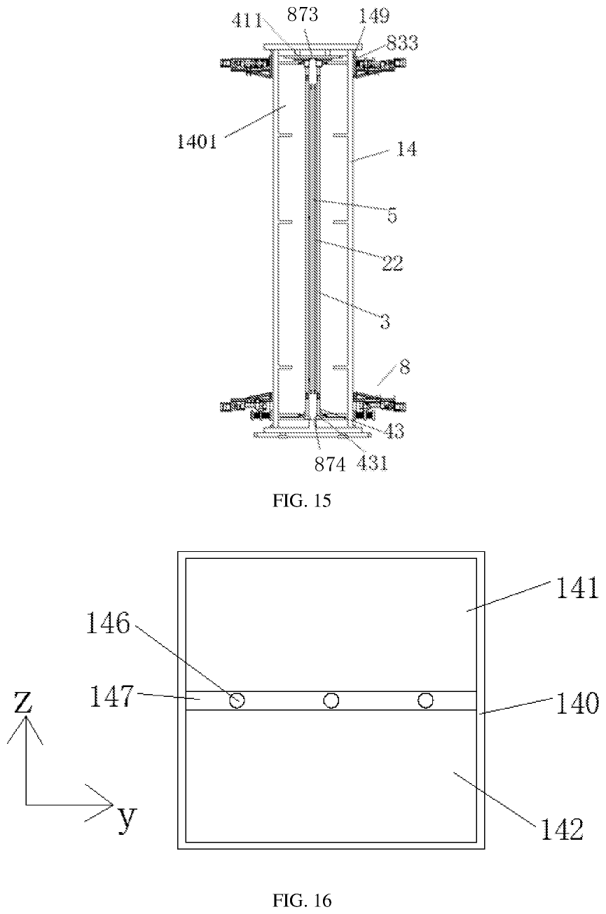

As shown in FIG. 15, a pair of loading plate apparatus 3 is provided in the vacuum chamber 14, the loading plate apparatus 3 is symmetrically disposed relative to the axis of the vacuum chamber 14, and the plurality of variable distance structures 8 are respectively disposed on both sides of the chamber door of the vacuum chamber 14. The plurality of variable distance structures 8 adjust the distance between a pair of loading plate apparatuses 3 and at least one of the spray apparatus 5 and the heat source 22.

In other embodiments, the docking block 842 of the docking component 84 may be directly connected to the loading plate apparatus 3.

In the implementation process of this embodiment, the object to be coated 7 is loaded on the loading plate apparatus 3, and the limit support mechanism 41 suspends and limits the loading plate apparatus 3; the limit mechanism 43 limits the loading plate apparatus 3 below, and the power mechanism 42 drives the loading plate apparatus 3 to move along the moving path; the power mechanism 42 transports the loading plate apparatus 3 to the loading preheating chamber 12, the temperature regulating device 20 inside the preheating chamber 12 is activated, and the thermal radiation of the temperature regulating device 20 preheats the object to be coated 7 loaded on the loading plate apparatus 3 before the coating process; the power mechanism 42 transports the loading plate apparatus 3 to the first sub coating vacuum chamber 13, the transmission structure 4 starts, and adjusts the distance between the object to be coated 7 loaded on the loading plate apparatus 3, and the spray apparatus 5 in the first sub coating vacuum chamber 13 and the heat source 22 to the set value; the temperature regulating device 20 in the first sub coating vacuum chamber 13 starts, the heat source 22 starts, the processing gas released by the spray apparatus 5 is decomposed through the heat source 22, and coating an intrinsic amorphous silicon film on one side of the object to be coated 7; the power mechanism 42 transports the loading plate apparatus 3 to the second sub coating vacuum chamber 15, the transmission structure 4 starts, and adjusts the distance between the object to be coated 7 loaded on the loading plate apparatus 3, and the spray apparatus 5 and heat source 22 in the second sub coating vacuum chamber 15 to the set value, the temperature regulating device 20 in the second sub coating vacuum chamber 15 starts, and the heat source 22 starts; the processing gas released by the spray apparatus 5 is decomposed through the heat source 22, and coating an N-type doped silicon-based thin film on one side of the object to be coated 7; the power mechanism 42 transports the loading plate apparatus 3 to the loading plate conversion vacuum chamber 16; a conversion mechanism is provided inside the loading plate conversion vacuum chamber 16, which converts the loading plate apparatus 3 on one side of the transmission structure 4 to the other side of the transmission structure 4 through the conversion mechanism; the positions of the loading plate apparatus 3 on both sides of the transmission structure 4 are replaced, and the object to be coated loaded on the loading plate apparatus 3 faces outward from the chamber, the uncoated surface is facing the heat source 22; the power mechanism 42 transports the shifted loading plate apparatus 3 to the third sub coating vacuum chamber 17, and the transmission structure 4 starts, and adjusts the distance between the loaded object to be coated 7 in the loading plate apparatus 3, the spray apparatus 5 in the third sub coating vacuum chamber 17 and the heat source 22 to the set value. The temperature regulating device 20 in the third sub coating vacuum chamber 17 starts, and the heat source 22 starts, the processing gas released by spray apparatus 5 is decomposed through the heat source 22, and coating an intrinsic amorphous silicon film on the other side of the object to be coated 7, which is the uncoated surface; the power mechanism 42 transports the loading plate apparatus 3 to the fourth sub coating vacuum chamber 18, and the transmission structure 4 starts, and adjusts the distance between the object to be coated 7 loaded on the loading plate apparatus 3, and the spray apparatus 5 and heat source 22 in the fourth sub coating vacuum chamber 18 to the set value, the temperature regulating device 20 in the fourth sub coating vacuum chamber 18 starts, and the heat source 22 starts, the processing gas released by the spray apparatus 5 is decomposed through the heat source 22, and coating a P-type doped silicon-based thin film on the other side of the object to be coated 7; the power mechanism 42 transports the loading plate apparatus 3 completely coated to the unloading heat dissipating chamber 19, a cooling structure is set inside the unloading heat dissipating chamber 19, which provides a room temperature gas for cooling the coated object; after the cooling is completed, the power mechanism 42 drives the loading plate apparatus 3 to flow out of the device. That is, the loading preheating chamber 12 is used to preheat the object to be coated 7, the first sub coating vacuum chamber 13, the second sub coating vacuum chamber 15, the third sub coating vacuum chamber 17, and the fourth sub coating vacuum chamber 18 are used to coat the object to be coated 7, the loading plate conversion vacuum chamber 16 is used to convert the coating surface of the object to be coated, and the unloading heat dissipating chamber 19 is used to provide a room temperature gas to cool the object to be coated 7.

This embodiment relies on the loading plate apparatus 3 that may be coated on both sides and the loading plate conversion vacuum chamber 16 to achieve the double-sided coating function of object to be coated 7 on a sealed production line. During the coating process, the object to be coated 7 converts the coating surface of the object to be coated in the loading plate conversion vacuum chamber 16, and the object to be coated no longer comes into contact with the atmosphere, thus eliminating the bad influence caused by water vapor, oxygen, dust, and so on in the air, and improving the production quality of the object to be coated 7.

In this embodiment, the entire vacuum chamber is distributed in a production line form, so that the moving path of the loading plate apparatus 3 may be shorted. At the same time, there is no need to add an additional automated flipping mechanism to convert the coating surface of the object to be coated, thus reducing equipment costs, saving occupied area of the equipment, improving the efficiency of site use, and achieving high equipment processing integration, high equipment operating efficiency, and low equipment costs.

Other connecting methods that enable the gear rack 415 to cooperate with the limit wheel 414 and enable the gear rack 415 to move relative to the limit wheel 414 are also within the protection scope of the present application.

As shown in FIG. 16, the difference between this embodiment and the above embodiment is that: the first chamber door 141 and the second chamber door 142 of the front chamber door component 1410 in the above embodiment are distributed along the y-direction, the third chamber door 143 and the fourth chamber door 144 of the back chamber door component 1430 are distributed along the y-direction, and the chamber door of at least one of the front chamber door component 1410 and the back chamber door component 1430 opens or closes in the y-direction, while in this embodiment, the first chamber door 141 and the second chamber door 142 of the front chamber door component 1410 are distributed along the z-direction, while the third chamber door 143 and the fourth chamber door 144 of the rear chamber door component 1430 are distributed along the z-direction. The chamber door of at least one of the front chamber door component 1410 and the back chamber door component 1430 opens or closes in the z-direction.

The difference between this embodiment and the above embodiment is that: in the above embodiment, the valve chamber 6, the first coating vacuum chamber, the second coating vacuum chamber, and the loading plate conversion vacuum chamber 16 form a coating production line for producing the object to be coated. In this embodiment, the valve chamber 6, the first coating vacuum chamber, the second coating vacuum chamber, and the loading plate conversion vacuum chamber 16 form several coating production lines for the object to be coated. One production line may be used to coat the first side of object to be coated 7, and a production line may be used for coating the second side of the object to be coated 7. In addition, the loading plate conversion vacuum chamber 16 may also form a production line for converting the coating surface of the object to be coated. The object to be coated 7 converts the coating surface in a sealed loading plate conversion vacuum chamber 16. The object to be coated 7 no longer comes into contact with the atmosphere, thus eliminating the bad influence caused by water vapor, oxygen, dust, and so on in the air, and improving the production quality of the object to be coated 7.

In other embodiments, the variable distance transmission component 82 may adopt a gear rack transmission structure, where the gear and gear rack are connected in mesh, the gear rack is connected to the moving flange 831, and the variable distance power component 81 drives the gear to rotate. The gear drives the gear rack to move through the meshing effect, and the movement of gear rack drives the moving flange 831 to move. The subsequent distance adjustment process is the same as in Example 1, and will not be repeated here. Alternatively, the variable distance transmission component 82 may adopt a gear transmission belt transmission structure, where the gear drives the transmission belt transmission, and the moving flange 831 is set on the transmission belt. The variable distance power component 81 drives the gear to rotate, the gear drives the transmission belt to move, and the movement of the transmission belt drives the moving flange 831 to move. The subsequent distance adjustment process is the same as in Example 1, and will not be elaborated here. Alternatively, the variable distance transmission component 82 may adopt a cam structure. The variable distance power component 81 is connected to the active end of the cam, and the driven end of the cam is connected to the moving flange 831. The variable distance power component 81 drives the cam to rotate, and the driven end of the cam drives the moving flange 831 to move. The subsequent distance adjustment process is the same as in Example 1, and will not be repeated here.

In other embodiments, the telescopic component 83 may adopt a multi-layer sleeve structure, with the outer sleeve connected to the vacuum chamber 14, the inner sleeve located inside the outer sleeve, the inner sleeve sliding connected to the outer sleeve and maintaining sealing, the first end of the inner sleeve connected to the docking rod 841, and the second end of the inner sleeve connected to the variable distance transmission component 82, thereby achieving the movement of the docking rod 841 through the multi-layer sleeve structure.

In summary, the advantages of this application are as follows.
1) The present application may achieve the double-sided coating function of object to be coated on a sealed production line through the loading plate apparatus that may be coated on both sides and the loading plate conversion vacuum chamber to. During the coating process, the object to be coated converts the coating surface of the object to be coated in the loading plate conversion vacuum chamber, and the object to be coated no longer comes into contact with the atmosphere, thus eliminating the bad influence caused by water vapor, oxygen, dust, and so on in the air, and improving the production quality of the object to be coated.
2) In the present application, the entire vacuum chamber is distributed in a production line form, so that the moving path of the loading plate apparatus may be shorted. At the same time, there is no need to add an additional automated flipping mechanism to convert the coating surface of the object to be coated, thus reducing equipment costs, saving occupied area of the equipment, improving the efficiency of site use, and achieving high equipment processing integration, high equipment operating efficiency, and low equipment costs.
3) In the present application, the dry pump docking flange is set on the beam frame, which no longer interferes with the opening of the chamber door and improves maintenance efficiency.
4) The present application reduces the weight of a single chamber door, reduces the load on the hinge 148, and improves the service life of the hinge 148 through a multi chamber door structure. At the same time, the size of the chamber door is reduced, thereby reducing the difficulty of production and processing. Under the same conditions, smaller sizes are not easily deformed, which may improve the strength and service life of the chamber door in this embodiment, and have better sealing performance, which may effectively ensure the vacuum degree of the vacuum chamber. And the area occupied by the opening of the chamber door in this embodiment is half or less comparing to the structure in the prior art, thus reducing the occupied area of the equipment.
5) In the present application, the front chamber door component and the back chamber door component are opened synchronously, which increases the maintenance space of the equipment, facilitates personnel operation, and improves maintenance efficiency.
6) This application adjusts the distance between the object to be coated loaded by the loading plate apparatus, and at least one of the spray apparatus and the heat source through variable distance transmission components and telescopic components. The adjustment range is wide, which may meet the spacing requirements of different silicon wafers and processes. At the same time, it achieves the technical effect of automatic spacing adjustment, improves production efficiency, and meets the needs of automated assembly line production.
7) In the present application, the fixing flange of the telescopic component is connected to the docking flange on the outer side of the vacuum chamber, the sealing ring is disposed between the fixing flange and the docking flange to ensure the sealing between the corrugated pipe and the vacuum chamber. The moving flange is connected to the variable distance transmission component to achieve reciprocating movement of the loading plate apparatus along the axial direction, and to achieve the adjustment of the distance between the object to be coated loaded by the loading plate apparatus, and at least one of the spray apparatus and the heat source.
8) In the present application, the power mechanism drives the loading plate apparatus to move through the meshing effect of the power gear and the gear rack. The transmission efficiency of the power gear and the gear rack is higher than the transmission efficiency of a roller structure used in the prior art, and the limit accuracy of the transmission between the power gear and the gear rack is high, so that the difference between the operating position of the loading plate apparatus in the chamber and the theoretical value is small, which is conducive to the overall refined management of the equipment. The meshing position between the power gear and the gear rack is located at the top of the loading plate apparatus, so that for the large loading plate of the mass production machine, the operational stability of the loading plate apparatus is improved, thus effectively reducing the fragment risk of the object to be coated.
9) In the present application, through the slot connection between the gear rack and the limit wheel, the limit for the loading plate apparatus is achieved, so that the limit of the loading plate apparatus no longer depends on the shape, thus improving the limit accuracy of the loading plate apparatus, reducing the machining difficulty of the overall workpiece, and reducing equipment costs.
10) In the present application, at least one power mechanism is provided, and at least one power mechanism is distributed, along the moving direction of the loading plate apparatus, in the vacuum chamber. At least one support component is provided, and at least one support component is distributed, along the moving direction of the loading plate apparatus, on the bracket, thereby ensuring the limit function and power transmission requirements of the loading plate apparatus during a movement, and ensuring the operational stability of the loading plate apparatus.

What is claimed is:

1. A vacuum coating device, comprising:
a plurality of valve chambers;
a processing chamber, comprising a first coating vacuum chamber, a second coating vacuum chamber and a loading plate conversion vacuum chamber, wherein the loading plate conversion vacuum chamber is connected to the first coating vacuum chamber and the second coating vacuum chamber, the loading plate conversion vacuum chamber is configured to convert a coating surface of an object to be coated, the first coating vacuum chamber and the loading plate conversion vacuum chamber are connected through one of the plurality of valve chambers, the second coating vacuum chamber and the loading plate conversion vacuum chamber are connected through another of the plurality of valve chambers, and the first coating vacuum chamber, the second coating vacuum chamber, the loading plate conversion vacuum chamber, and the plurality of valve chambers are configured to form a coating production line for producing the object to be coated;
a loading plate apparatus, disposed within the processing chamber, and configured to load the object to be coated;
a spraying apparatus, disposed within the processing chamber, and configured to spray a processing gas; and
a heating apparatus, configured to heat the processing chamber to a temperature reaching a reaction temperature of the object to be coated and the processing gas.

2. The vacuum coating device according to claim 1, wherein at least one of the first coating vacuum chamber, the second coating vacuum chamber, and the loading plate conversion vacuum chamber comprises a vacuum chamber, and
the vacuum chamber comprises:
a chamber frame;
a front chamber door component, connected to the chamber frame; and
a back chamber door component, connected to the chamber frame;
wherein the front chamber door component and the back chamber door component are disposed on both sides of the chamber frame.

3. The vacuum coating device according to claim 2, wherein the vacuum chamber further comprises:
a partition board, disposed on at least one side of the chamber frame;
a beam frame, disposed on a side, away from the chamber frame, of the partition board; and
at least one dry pump docking flange, disposed on the beam frame;
wherein the front chamber door component and the back chamber door component are hinged with the chamber frame.

4. The vacuum coating device according to claim 2, further comprising:
a transmission structure, comprising a limit support mechanism, a power mechanism, and a limit mechanism, wherein
the limit support mechanism is configured to limit an upper end of the loading plate apparatus, and the limit support mechanism comprises a gear rack connected to the loading plate apparatus;
the power mechanism comprises a power gear, the gear rack meshes with the power gear, and a meshing position of the power gear and the gear rack is located at a top of the loading plate apparatus; and
the limit mechanism is configured to limit a lower end of the loading plate apparatus.

5. The vacuum coating device according to claim 4, further comprising:
a variable distance structure, comprising a variable distance power component, a variable distance transmission component, a telescopic component, and a docking component, wherein
the variable distance power component is connected to the variable distance transmission component, the variable distance transmission component is connected to the telescopic component, the telescopic component is connected to the docking component, and the docking component is connected to the loading plate apparatus; and
the variable distance power component controls movement of the loading plate apparatus through the variable distance transmission component, the telescopic component and the docking component.

6. The vacuum coating device according to claim 5, wherein the loading plate apparatus is disposed inside the vacuum chamber through the limit support mechanism and the limit mechanism; and
the docking component comprises a docking rod and a docking block, a first end of the docking rod is connected to the telescopic component, a second end of the docking rod is connected to the docking block, the docking block is disposed inside the vacuum chamber, and the docking block is connected to the loading plate apparatus through the limit support mechanism.

7. The vacuum coating device according to claim 5, wherein the limit support mechanism comprises a bracket, and the limit mechanism comprises a limit bracket; and
the vacuum coating device further comprises a sliding apparatus, and the sliding apparatus comprises:
a first sliding apparatus, disposed within the vacuum chamber, is disposed between the bracket and the vacuum chamber, wherein the first sliding apparatus comprises a fixing plate and a sliding block, the fixing plate is connected to the vacuum chamber, the sliding block is connected to the bracket, and the sliding block is slidably connected to the fixing plate, so that the sliding block is configured to drive the bracket to move along a direction perpendicular to a length direction of the bracket; and
a second sliding apparatus, disposed within the vacuum chamber, is disposed between the limit bracket and the vacuum chamber, wherein the second sliding apparatus is connected to the vacuum chamber and the limit bracket, and the second sliding apparatus is configured to drive the limit bracket to move along a direction perpendicular to a length direction of the limit bracket.

8. The vacuum coating device according to claim 4, wherein
the first coating vacuum chamber comprises a first sub coating vacuum chamber and a second sub coating vacuum chamber, the first sub coating vacuum chamber and the second sub coating vacuum chamber are configured to coat a first side of the object to be coated; and
the second coating vacuum chamber comprises a third sub coating vacuum chamber and a fourth sub coating vacuum chamber, the third sub coating vacuum chamber and the fourth sub coating vacuum chamber are configured to coat a second side of the object to be coated.

9. The vacuum coating device according to claim 8, wherein
the valve chamber between the first sub coating vacuum chamber and the second sub coating vacuum chamber is a first valve chamber, the valve chamber between the second sub coating vacuum chamber and the loading plate conversion vacuum chamber is a second valve chamber, the valve chamber between the loading plate conversion vacuum chamber and the third sub coating vacuum chamber is a third valve chamber, and the valve chamber between the third sub coating vacuum chamber and the fourth sub coating vacuum chamber is a fourth valve chamber;
the first sub coating vacuum chamber, the first valve chamber, the second sub coating vacuum chamber, the second valve chamber, the loading plate conversion vacuum chamber, the third valve chamber, the third sub coating vacuum chamber, the fourth valve chamber and the fourth sub coating vacuum chamber are connected sequentially; and
a moving path of the loading plate apparatus starts from the first sub coating vacuum chamber, sequentially passes through the first valve chamber, the second sub coating vacuum chamber, the second valve chamber, the loading plate conversion vacuum chamber, the third valve chamber, the third sub coating vacuum chamber, and the fourth valve chamber, and ends at the fourth sub coating vacuum chamber.

10. The vacuum coating device according to claim 4, wherein the limit support mechanism further comprises:
a bracket;
at least one support component, disposed on the bracket along a moving direction of the loading plate apparatus; and
a support plate, connected to the loading plate apparatus;
wherein a number of the power mechanism is plural, and a plurality of power mechanisms are disposed within the vacuum chamber and distributed along the moving direction of the loading plate apparatus.

11. The vacuum coating device according to claim 10, wherein
the support component comprises a wheel mounting bracket, a support wheel, and a limit wheel;
the support wheel and the limit wheel are disposed on the wheel mounting bracket, and the limit wheel is disposed below the gear rack and is configured to form a slot connection with the gear rack; and
a number of the support component is plural, a plurality of support components are distributed along the moving direction of the loading plate apparatus, the support plate is disposed at the top of the loading plate apparatus, the support wheel is disposed on a lower side of the support plate, and the support wheel snugly fits with the support plate and supports the support plate during a movement of the loading plate apparatus.

12. The vacuum coating device according to claim 11, wherein
a first block is disposed on a lower end face of the gear rack, a first slot is disposed on the limit wheel, and the first block is buckled into the first slot to form the slot connection between the limit wheel and the gear rack; or
a second slot is disposed on the lower end face of the gear rack, a second block is disposed on the limit wheel, and the second block is buckled into the second slot to form the slot connection between the limit wheel and the gear rack.

13. The vacuum coating device according to claim 11, wherein
the limit mechanism comprises a limit bracket and a plurality of limit components, a length direction of the limit bracket is parallel to the moving direction of the loading plate apparatus, the limit bracket is connected to a bottom inside the vacuum chamber, and the plurality of limit components are disposed on the limit bracket along the moving direction of the loading plate apparatus; and
the limit component comprises:
a limit fixing plate, connected to the limit bracket;
two limit rods, symmetrically disposed on both sides of the limit fixing plate; and
two rollers, respectively connected to the limit rods and respectively in contact with both sides of the lower end of the loading plate apparatus.

14. The vacuum coating device according to claim 10, wherein the power mechanism further comprises:
a motor component, disposed outside the vacuum chamber;
a magnetic fluid, wherein a first end of the magnetic fluid is connected to the motor component and is disposed outside the vacuum chamber, and a second end of the magnetic fluid is disposed inside the vacuum chamber;
a coupling, disposed inside the vacuum chamber and connected to the second end of the magnetic fluid;
a power shaft, disposed inside the vacuum chamber and connected to the coupling, and the power gear is disposed on an outer surface of the power shaft; and
a bearing seat, disposed inside the vacuum chamber and at a top of the vacuum chamber, wherein the bearing seat is configured to carry the power shaft to rotate relative to the bearing seat.

15. The vacuum coating device according to claim 8, wherein
the processing chamber further comprises a loading preheating chamber and an unloading heat dissipating chamber; and
the loading preheating chamber is connected to the first sub coating vacuum chamber through the valve chamber, and the unloading heat dissipating chamber is connected to the fourth sub coating vacuum chamber through the valve chamber.

16. The vacuum coating device according to claim 15, wherein
the heating apparatus comprises a temperature regulating device and a heat source;
the loading preheating chamber, the first coating vacuum chamber, the second coating vacuum chamber, and the loading plate conversion vacuum chamber are provided with a pair of temperature regulating devices individually, and each of the pair of temperature regulating devices are symmetrically disposed relative to a centerline of the vacuum coating device; and
the first coating vacuum chamber provided with the heat source disposed at a centerline of the first coating vacuum chamber, and the second coating vacuum chamber provided with the heat source disposed at a centerline of the second coating vacuum chamber.

17. The vacuum coating device according to claim 16, wherein the loading preheating chamber comprises a loading chamber and a preheating chamber, the loading chamber and the preheating chamber are connected through the valve chamber, and the temperature regulating device is disposed inside the preheating chamber.

18. The vacuum coating device according to claim 17, wherein the temperature regulating devices inside the preheating chamber and the loading plate conversion vacuum chamber are heaters, and the temperature regulating devices inside the first coating vacuum chamber and the second coating vacuum chamber are coolers.

19. The vacuum coating device according to claim 16, wherein the first coating vacuum chamber and the second coating vacuum chamber are provided with a pair of spray apparatuses individually, and for either of the first coating vacuum chamber and the second coating vacuum chamber, the pair of spray apparatuses are symmetrically disposed relative to the heat source.

20. The vacuum coating device according to claim 19, wherein
for either of the loading preheating chamber and the loading plate conversion vacuum chamber, the transmission structure and the temperature regulating device are sequentially distributed, along a direction from a centerline of the vacuum chamber to an outside of the vacuum chamber, and
for either of the first coating vacuum chamber and the second coating vacuum chamber, the heat source, the spray apparatus, the transmission structure, and the temperature regulating device are sequentially distributed inside, along the direction from the centerline of the vacuum chamber to the outside of the vacuum chamber.
